(19) United States
(12) Patent Application Publication
(10) Pub. No.: US 2022/0054989 A1
(43) Pub. Date: Feb. 24, 2022

(54) CHEMICAL LIQUID APPLICATION APPARATUS AND VISCOSITY ADJUSTMENT BOTTLE

(71) Applicant: Kioxia Corporation, Tokyo (JP)

(72) Inventor: Takanori FUKUSUMI, Kuwana (JP)

(73) Assignee: Kioxia Corporation, Tokyo (JP)

(21) Appl. No.: 17/200,045

(22) Filed: Mar. 12, 2021

(30) Foreign Application Priority Data
Aug. 18, 2020 (JP) 2020-138231

(51) Int. Cl. B01F 3/08; B05D 3/12

(52) U.S. Cl. CPC B01F 3/0865; B01F 2003/0896; B05D 3/12

(57) ABSTRACT

A chemical liquid application apparatus according to one embodiment includes: a processing unit which applies a chemical liquid to a substrate; and a viscosity adjustment unit including a viscosity adjustment bottle which mixes a chemical liquid and a diluent. The viscosity adjustment bottle includes a first introduction port into which the chemical liquid is introduced, a second introduction port into which the diluent diluting the chemical liquid is introduced, a porous body which is connected to the first and second introduction ports and includes a plurality of holes through which the chemical liquid and the diluent introduced from the first and second introduction ports flow, and a discharge port which is connected to the porous body and from which the mixture of the chemical liquid and the diluent is discharged.

### CROSS-REFERENCE TO RELATED APPLICATIONS

This application is based upon and claims the benefit of priority from Japanese Patent Application No. 2020-138231, filed on Aug. 18, 2020; the entire contents of which are incorporated herein by reference.

### FIELD

Embodiments described herein relate generally to a chemical liquid application apparatus and a viscosity adjustment bottle.

### BACKGROUND

As one of semiconductor device manufacturing devices, there is a chemical liquid application apparatus that applies a chemical liquid onto a substrate to form an applied film. When the applied film is formed on the substrate, a film thickness of the applied film can be adjusted, for example, by varying a viscosity of the chemical liquid. However, each time an applied film having a different film thickness is formed, a chemical liquid having a different viscosity should be set in the device, which results in causing trouble.

### BRIEF DESCRIPTION OF THE DRAWINGS

FIG. 1 is a diagram illustrating an example of a configuration of a chemical liquid application apparatus according to an embodiment;

FIGS. 2A to 2E are diagrams illustrating an example of a configuration of a viscosity adjustment bottle according to the embodiment; and

FIG. 3 is a flowchart illustrating an example of a procedure of chemical liquid application processing by the chemical liquid application apparatus according to the embodiment.

### DETAILED DESCRIPTION

A chemical liquid application apparatus according to one embodiment includes: a processing unit which applies a chemical liquid to a substrate; a chemical liquid supply unit that is capable of connecting a supply source of the chemical liquid; a diluent supply unit that is capable of connecting a supply source of a diluent diluting the chemical liquid is connected; a viscosity adjustment unit including a viscosity adjustment bottle to which the chemical liquid and the diluent are supplied from the chemical liquid supply unit and the diluent supply unit, and which mixes the chemical liquid and the diluent; and a mixture supply unit which supplies a mixture of the chemical liquid and the diluent to the processing unit. The viscosity adjustment bottle includes a first introduction port into which the chemical liquid is introduced, a second introduction port into which the diluent diluting the chemical liquid is introduced, a porous body which is connected to the first and second introduction ports and includes a plurality of holes through which the chemical liquid and the diluent introduced from the first and second introduction ports flow, and a discharge port which is connected to the porous body and from which the mixture of the chemical liquid and the diluent is discharged.

Hereinafter, the present invention will be described in detail with reference to the drawings. Note that the present invention is not limited by the following embodiments. Further, components in the following embodiments include components that can be easily assumed by those skilled in the art or components that are substantially identical.

(Configuration Example of Chemical Liquid Application Apparatus)

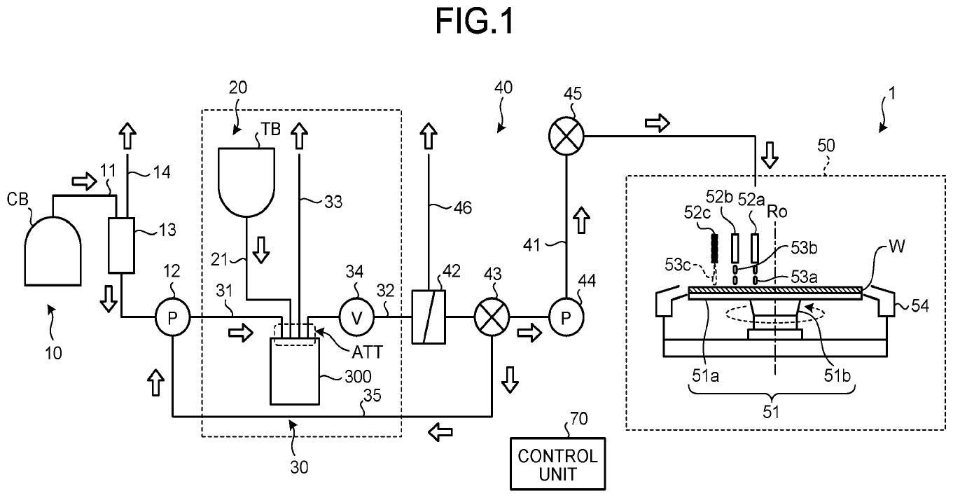

FIG. 1 is a diagram illustrating an example of a configuration of a chemical liquid application apparatus 1 according to an embodiment. As illustrated in FIG. 1, the chemical liquid application apparatus 1 includes a chemical liquid supply unit 10, a diluent supply unit 20, a viscosity adjustment unit 30, a mixture supply unit 40, a processing unit 50, and a control unit 70. With this configuration, the chemical liquid application apparatus 1 applies a chemical liquid onto a wafer W as a substrate to form an applied film.

Examples of the applied film formed by the chemical liquid application apparatus 1 include a mask film such as a photoresist film, an underlayer film such as a Spin On Carbon (SOC) film, an intermediate film/insulating film such as a Spin On Glass (SOG) film, a flattening film flattening a surface of the wafer W, and the like.

The processing unit 50 includes a spinner 51, a plurality of nozzles 52a, 52b, and 52c, and a cup 54.

The spinner 51 includes a support 51a and a spin motor 51b. The support 51a has a substantially disk-shaped top surface shape. The wafer W is placed on a top surface of the support 51a. The support 51a includes a spin chuck (not illustrated). The spin chuck fixes and holds the wafer W by, for example, vacuum suction.

The spin motor 51b is provided below the support 51a. The spin motor 51b rotates the support 51a along a rotation axis Ro at a predetermined rotation speed to rotate the wafer W supported by the support 51a. By rotating the wafer W, the spin motor 51b spreads the chemical liquid supplied onto the wafer W in a radial direction (to the side of an edge) of the wafer W by a centrifugal force. Further, the spin motor 51b rotates the wafer W at a predetermined speed to shake off the chemical liquid remaining on the wafer W by the centrifugal force.

The cup 54 is disposed on the side of the edge of the support 51a. The cup 54 has an annular shape so that the chemical liquid shaken off from the wafer W can be received. As a result, the cup 54 collects the chemical liquid shaken off by the wafer W.

Each of the plurality of nozzles 52a, 52b, and 52c is configured to outflow a predetermined chemical liquid or the like onto the wafer W. The nozzle 52a drops, for example, a chemical liquid 53a, which is a raw material for the applied film, onto the wafer W. The nozzle 52b drops, for example, a thinner 53b, which removes an excess chemical liquid from the wafer W, onto the wafer W. The nozzle 52c blows, for example, inert gas 53c such as N₂ gas onto the wafer W to further remove the excess chemical liquid and the like.

Each of the nozzles 52a, 52b, and 52c is installed at a tip of a scan arm (not illustrated) and is moved by the scan arm. The scan arm is provided so as to be movable between a center position and an edge position of the wafer W.

Further, the nozzles 52a, 52b, and 52c are connected to supply pipes, and a bottle is connected to each of these supply pipes. FIG. 1 illustrates only supply pipes 11, 31, and 41 connected to the nozzle 52a and a chemical liquid bottle CB. With this configuration, each of the nozzles 52a, 52b, and 52c can supply the predetermined chemical liquid or the like while moving along the radial direction of the wafer W.

As described above, the processing unit 50 forms the applied film on the wafer W by, for example, a spin coating method. However, the processing unit 50 may form the applied film on the wafer W by a method other than the spin coating method such as a raster scan method.

The chemical liquid supply unit 10, the diluent supply unit 20, the viscosity adjustment unit 30, and the mixture supply unit 40 are connected to the nozzle 52a and outflow the chemical liquid from the chemical liquid bottle CB to the processing unit 50.

The chemical liquid supply unit 10 includes the supply pipe 11 to which the chemical liquid bottle CB to be a chemical liquid supply source can be connected, a pump 12 connected to the supply pipe 11, a degassing tank 13 provided between the chemical liquid bottle CB of the supply pipe 11 and the pump 12, and an exhaust pipe 14 connected to the degassing tank 13.

The chemical liquid that is the raw material of the applied film is contained in the chemical liquid bottle CB. By driving the pump 12, the chemical liquid flows from the chemical liquid bottle CB into the supply pipe 11. Further, the chemical liquid is temporarily stored in the degassing tank 13 and degassed, and then outflowed to the viscosity adjustment unit 30 by the pump 12. Gas such as bubbles generated from the chemical liquid is exhausted from the exhaust pipe 14.

The diluent supply unit 20 includes a supply pipe 21 to which a diluent bottle TB, which is a diluent supply source, can be connected. A diluent for diluting the chemical liquid is contained in the diluent bottle TB. As described later, the viscosity of the chemical liquid can be varied in various ways by diluting the chemical liquid with the diluent at a predetermined ratio. Normally, the viscosity of the chemical liquid before dilution is highest, and the viscosity of the chemical liquid decreases as a dilution ratio increases. The diluent is outflowed to the viscosity adjustment unit 30 through the supply pipe 21.

Here, as the diluent, for example, various solvents such as cyclohexanone (CAS No. 108-94-1), γ-butyrolactone (CAS No. 96-48-0), propylene glycol monomethyl ether (PGME: CAS No. 107-98-2), propylene glycol monomethyl ether acetate (PGMEA: CAS No. 108-65-6), propylene glycol monoethyl ether (PGEE: CAS No. 1569-02-4), methyl 3-methoxypropionate (MMP: CAS No. 3852-09-3), butyl acetate (CAS No. 123-86-4), 2-heptanone (CAS No. 110-43-0), and N-methyl-2-pyrrolidone (NMP: CAS No. 872-50-4) can be used.

The viscosity adjustment unit 30 includes a viscosity adjustment bottle attachment unit ATT, a viscosity adjustment bottle 300, a supply pipe 31 connecting the pump 12 and the viscosity adjustment bottle 300, a supply pipe 32 and an exhaust pipe 33 which are connected to the viscosity adjustment bottle 300, a viscometer 34 provided in the supply pipe 32, and a supply pipe 35 connecting the pump 12 and a valve 43 described later. The supply pipe 21 described above is also connected to the viscosity adjustment bottle 300. Note that the valve 43 may be included in the viscosity adjustment unit 30.

The viscosity adjustment bottle 300 is configured to be attachable to the viscosity adjustment bottle attachment unit ATT included in the viscosity adjustment unit 30. The viscosity adjustment bottle attachment unit ATT includes the supply pipes 21, 31, 32, and 33 connected to the viscosity adjustment bottle 300. A detailed configuration of the viscosity adjustment bottle attachment unit ATT will be described later.

The chemical liquid is supplied from the supply pipe 31 to the viscosity adjustment bottle 300, and the diluent is supplied from the supply pipe 21 to the viscosity adjustment bottle 300. The viscosity adjustment bottle 300 mixes the supplied chemical liquid and diluent to produce a mixture having a predetermined viscosity. When the chemical liquid and the diluent are mixed, gas such as bubbles generated from the chemical liquid and the diluent is exhausted from the exhaust pipe 33. A detailed configuration of the viscosity adjustment bottle 300 will be described later.

The mixture produced by the viscosity adjustment bottle 300 flows from the supply pipe 32 into the viscometer 34. The viscometer 34 measures the viscosity of the inflowing mixture. When the mixture has a desired viscosity, the valve 43 is switched, and the mixture is outflowed to the side of the downstream processing unit 50. When the mixture does not have the desired viscosity, the valve 43 is switched, and the mixture returns to the pump 12 through the supply pipe 35 and circulates in a path of the supply pipe 31, the viscosity adjustment bottle 300, the supply pipe 32, the valve 43, and the supply pipe 35 until the mixture has the desired viscosity. As described above, the valve 43 may have a configuration such as a three-way valve.

The mixture supply unit 40 includes a supply pipe 41 connected to the nozzle 52a, a filter 42, a valve 43, a pump 44, and a valve 45 provided in the supply pipe 41 and disposed sequentially from the upstream side, and an exhaust pipe 46 connected to the filter 42. However, the valve 43 may be provided on the upstream side of the filter 42. Further, the valve 43 may be included in the viscosity adjustment unit 30.

The mixture outflowed from the viscosity adjustment unit 30 passes through the filter 42 and reaches the valve 43. Gas such as bubbles generated when the mixture passes through the filter 42 is exhausted through the exhaust pipe 46 connected to the filter 42.

The mixture that has reached the valve 43 is outflowed to the side of the processing unit 50 or returned to the side of the pump 12 through the supply pipe 35 by switching of the valve 43. The mixture outflowed to the side of the processing unit 50 is supplied to the processing unit 50 through the valve 45 and the nozzle 52a by driving of the pump 44.

As described above, FIG. 1 illustrates only the mechanism for supplying the chemical liquid to the nozzle 52a. However, a mechanism for supplying the thinner to the nozzle 52b may also be configured in the same manner as the mechanism for supplying the chemical liquid to the nozzle 52a, except that the mechanism does not have the diluent supply unit 20 shown by the broken line square frame, the viscosity adjustment unit 30, and the valve 43.

The control unit 70 includes a central processing unit (CPU), a read only memory (ROM), a random access memory (RAM), and the like, and is configured as a computer that controls the entire chemical liquid application apparatus 1.

That is, the control unit 70 controls amounts of the chemical liquid (mixture) 53a, the thinner 53b, and the inert gas 53c dropped from the nozzles 52a, 52b, and 52c onto the wafer W. Further, the control unit 70 controls positions and movement speeds of the nozzles 52a, 52b, and 52c on the wafer W. Further, the control unit 70 controls the rotation start/stop timing and rotation speed of the spinner 51.

Further, the control unit 70 controls amounts of the chemical liquid and the diluent outflowed from the chemical liquid bottle CB and the diluent bottle TB. Further, the control unit 70 controls the pumps 12 and 44 and the valves 43 and 45 so as to outflow the chemical liquid, the diluent, and the mixture thereof. Further, the control unit 70 measures the viscosity of the mixture discharged from the viscosity adjustment bottle 300 by controlling the viscometer 34, adjusts the outflow amounts of the chemical liquid and the diluent on the basis of the viscosity of the mixture, and supplies the mixture to the processing unit 50 or sends the mixture back to the pump 12 by controlling the valve 43.

(Configuration Example of Viscosity Adjustment Bottle)

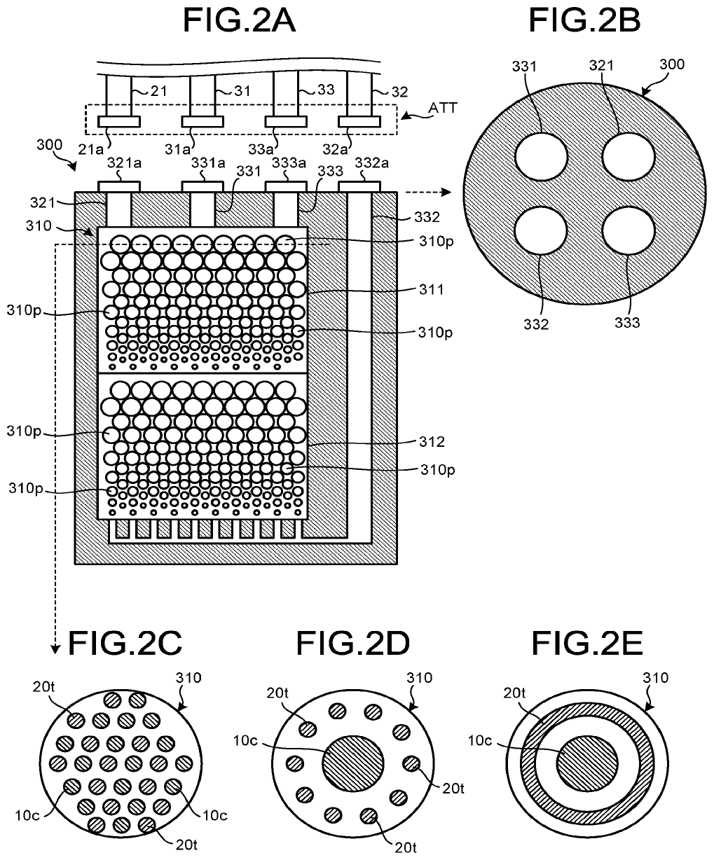

Next, a configuration example of the viscosity adjustment bottle 300 will be described using FIGS. 2A to 2E. FIGS. 2A to 2E are diagrams illustrating an example of a configuration of the viscosity adjustment bottle 300 according to the embodiment. FIG. 2A is a longitudinal cross-sectional view of the viscosity adjustment bottle 300, and FIG. 2B is a top view of the viscosity adjustment bottle 300. FIGS. 2C to 2E are transverse cross-sectional views of a porous body 310 included in the viscosity adjustment bottle 300.

As illustrated in FIGS. 2A and 2B, the viscosity adjustment bottle 300 includes introduction ports 321a and 331a, a discharge port 332a, flow paths 321, 331, and 332, and a porous body 310. Further, the viscosity adjustment bottle 300 preferably includes a flow path 333 and an exhaust port 333a for exhausting gas such as bubbles generated inside.

The introduction ports 321a and 331a, the discharge port 332a, and the exhaust port 333a are provided on a top surface of the viscosity adjustment bottle 300 and are connected to the viscosity adjustment bottle attachment unit ATT provided in the chemical liquid application apparatus 1. However, the number and arrangement of the introduction ports 321a and 331a, the discharge port 332a, and the exhaust port 333a on the top surface of the viscosity adjustment bottle 300 are not limited to the example of FIG. 2B, and various different configurations can be used.

The viscosity adjustment bottle attachment unit ATT includes the supply pipes 21, 31, and 32, the exhaust pipe 33, a outflow port 21a attached to the downstream end of the supply pipe 21, a outflow port 31a attached to the downstream end of the supply pipe 31, an inflow port 32a attached to the upstream end of the supply pipe 32, and an exhaust port 33a attached to the upstream end of the exhaust pipe 33.

The diluent is outflowed from the outflow port 21a to the viscosity adjustment bottle 300, and the chemical liquid is outflowed from the outflow port 31a to the viscosity adjustment bottle 300. From the viscosity adjustment bottle 300, the mixture flows into the inflow port 32a, and gas such as bubbles flows into the exhaust port 33a.

The introduction port 321a as the second introduction port is connected to the outflow port 21a as the second outflow port attached to the supply pipe 21. As a result, the diluent is introduced into the viscosity adjustment bottle 300 through the introduction port 321a. The introduction port 331a as the first introduction port is connected to the outflow port 31a as the first outflow port attached to the supply pipe 31. As a result, the chemical liquid is introduced into the viscosity adjustment bottle 300 through the introduction port 331a.

The discharge port 332a is connected to the inflow port 32a attached to the supply pipe 32. The mixture mixed by the viscosity adjustment bottle 300 is discharged from the discharge port 332a to the inflow port 32a. As a result, the mixture flows into the chemical liquid application apparatus 1 through the inflow port 32a.

The exhaust port 333a is connected to the exhaust port 33a attached to the exhaust pipe 33. Gas such as bubbles generated in the viscosity adjustment bottle 330 is exhausted from the exhaust port 333a to the exhaust port 33a. As a result, the gas is exhausted to the exhaust pipe 33 through the exhaust port 33a.

The introduction ports 321a and 331a are connected to the upstream end of the porous body 310 by the flow paths 321 and 331, respectively. As a result, the diluent and the chemical liquid introduced from the introduction ports 321a and 331a flow into the porous body 310 through the flow paths 321 and 331.

Here, by varying the number and arrangement of the introduction ports 321a and 331a, the chemical liquid and the diluent can be introduced at various positions near the upstream end of the porous body 310, as illustrated in FIGS. 2C to 2E.

In FIG. 2C, chemical liquids 10c and diluents 20t are introduced at random positions near the upstream end of the porous body 310 disposed in a grid shape. In FIG. 2D, the chemical liquids 10c are introduced into a substantially circular region including a center position near the upstream end of the porous body 310, and the diluents 20c are introduced at a plurality of positions arranged at predetermined intervals on the circumference surrounding the region. In FIG. 2E, the chemical liquids 10c are introduced into an annular region including the center position near the upstream end of the porous body 310, and the diluents 20c are introduced into a continuous circumferential region surrounding the region.

As described above, the chemical liquid and the diluent are separately introduced into the different flow paths of the porous body 310, and then joined and mixed in the porous body 310 as described later.

As illustrated in FIG. 2A, the porous body 310 is made of, for example, a porous resin or the like, and has a plurality of fine holes 310p. The plurality of holes 310p is continuously or intermittently connected, so that a plurality of flow paths through which the chemical liquid and the diluent can flow are formed through the porous body 310 from the upstream end to the downstream end.

In a state where the viscosity adjustment bottle 300 is attached to the chemical liquid application apparatus 1, the upstream side of the porous body 310 is preferably disposed above the downstream side of the porous body 310 in a direction of gravity. This facilitates the flow of the chemical liquid and the diluent from the upstream side to the downstream side due to the weight of the chemical liquid and the diluent.

Further, diameters of the holes 310p provided in the porous body 310 are different according to the positions from the upstream end to the downstream end of the porous body. At this time, the hole diameters preferably decrease from the upstream side to the downstream side.

With the above configuration, the chemical liquid and the diluent are mixed to generate a mixture while flowing from the upstream side to the downstream side of the porous body 310. The gas such as bubbles generated at this time is exhausted to the outside of the viscosity adjustment bottle 300 by the flow path 333 connecting the upstream end of the porous body 310 and the exhaust port 333a.

The porous body 310 is provided with a plurality of sub-bodies 311 and 312 arranged from the upstream side to the downstream side, so that a change in the hole diameter from the upstream side to the downstream side may be repeated a plurality of times. In the example of FIG. 2A, the porous body 310 includes the two sub-bodies 311 and 312 whose hole diameter decreases from the upstream side to the downstream side, but the number of sub-bodies 311 and 312 may be three or more.

Further, the sub-bodies 311 and 312 may have a configuration in which the hole diameter increases from the upstream side to the downstream side. Further, the upstream sub-body 311 is configured so that the hole diameter decreases from the upstream side to the downstream side, and the downstream sub-body 312 is configured so that the hole diameter increases from the upstream side to the downstream side.

In the configuration in which the hole diameter increases from the upstream side to the downstream side, the chemical liquid can be quickly flown on the upstream side where the viscosity of the chemical liquid is high, and the chemical liquid and the diluent are mixed more precisely on the downstream side. On the other hand, in the configuration in which the hole diameter increases from the upstream side to the downstream side, it can be expected that the chemical liquid and the diluent are quickly mixed at the initial stage of mixing.

A plurality of branched flow paths 332 are connected to the downstream end of the porous body 310. The branched flow paths 332 are aggregated and extend laterally to the porous body 310, and are connected to the discharge port 332a. As a result, the mixture produced by the porous body 310 flows into the chemical liquid application apparatus 1 from the discharge port 332a.

(Processing Example of Chemical Liquid Application Apparatus)

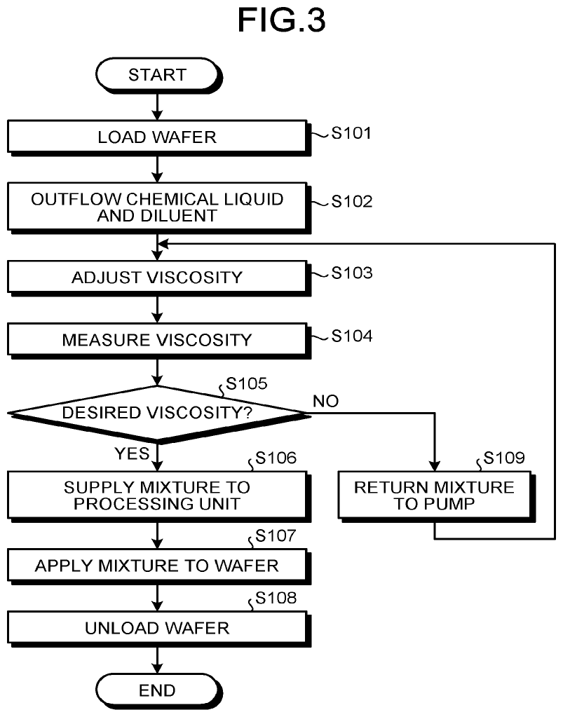

Next, a processing example of chemical liquid application in the chemical liquid application apparatus 1 according to the embodiment will be described using FIG. 3. FIG. 3 is a flowchart illustrating an example of a procedure of chemical liquid application processing by the chemical liquid application apparatus 1 according to the embodiment.

As illustrated in FIG. 3, the control unit 70 loads the wafer W into the processing unit 50 by a conveyance system (not illustrated) of the chemical liquid application apparatus 1 (step S101). The control unit 70 outflows the chemical liquid from the chemical liquid bottle CB and outflows the diluent from the diluent bottle TB, at a ratio suitable for the desired film thickness of the applied film formed on the wafer W (step S102).

The chemical liquid and the diluent that are outflowed from the chemical liquid bottle CB and the diluent bottle TB, respectively are introduced into the viscosity adjustment bottle 300 and discharged from the viscosity adjustment bottle 300 as a mixture whose viscosity has been adjusted in the porous body 310 (step S103).

The control unit 70 measures the viscosity of the mixture by the viscometer 34 (step S104), and determines whether or not the mixture has a desired viscosity (step S105). When the mixture does not have the desired viscosity (step S105: No), the control unit 70 switches the valve 43 to return the mixture to the pump 12 (step S109), and repeats the processing from step S103.

When the mixture has the desired viscosity (step S105: Yes), the control unit 70 switches the valve 43 to supply the mixture to the processing unit 50 (step S106). The control unit 70 applies the mixture to the wafer W by controlling the nozzle 52a (step S107). The control unit 70 unloads the wafer W to which the mixture has been applied from the processing unit 50 (step S108).

Then, the wafer W is heated by a baking mechanism (not illustrated) of the chemical liquid application apparatus 1, and an applied film having a desired film thickness is formed on the wafer W.

In this way, the chemical liquid application processing in the chemical liquid application apparatus 1 according to the embodiment ends.

(Summary)

In the processing by the chemical liquid application apparatus, a chemical liquid having an adjusted viscosity may be used in order to form an applied film having a desired film thickness on the wafer. However, when the film thickness of the applied film is changed, a bottle containing a different chemical liquid should be reattached to the chemical liquid processing device. Further, when a plurality of types of applied films having different film thicknesses is formed, a bottle should be attached to the chemical liquid application apparatus for each of a plurality of types of chemical liquids corresponding to the applied films, and the chemical liquid application apparatus may become large and expensive.

According to the chemical liquid application apparatus 1 of the embodiment, the viscosity adjustment unit 30 has the viscosity adjustment bottle 300 that mixes the chemical liquid and the diluent. As a result, a plurality of chemical liquids having different viscosities can be easily supplied. Therefore, it is not necessary to replace the chemical liquid bottle CB every time the film thickness of the applied film is changed, and downtime of the chemical liquid application apparatus 1 can be shortened and man-hours can be reduced. Further, it is not necessary to attach a plurality of chemical liquid bottles CB in order to form a plurality of types of applied films having different film thicknesses, and the chemical liquid application apparatus 1 can be miniaturized and reduced in price.

According to the chemical liquid application apparatus 1 of the embodiment, the viscosity adjustment unit 30 includes the viscosity adjustment bottle attachment unit ATT to which the viscosity adjustment bottle 300 can be attached. As a result, the viscosity adjustment bottle 300 can be easily attached.

According to the chemical liquid application apparatus 1 of the embodiment, the control unit 70 switches the valve 43 and controls the outflow destination of the mixture, on the basis of the measurement result by the viscometer 34. As a result, it is possible to prevent the mixture whose viscosity does not reach the desired viscosity from being supplied to the processing unit 50.

According to the viscosity adjustment bottle 300 of the embodiment, the porous body 310 through which the chemical liquid and the diluent can flow is provided. As a result, it is possible to generate a mixture in which the chemical liquid and the diluent having flown through the porous body 310 are mixed.

According to the viscosity adjustment bottle 300 of the embodiment, the diameters of the plurality of holes 310p in the porous body 310 are different according to the positions from the upstream side to the downstream side. This makes it possible to precisely mix the chemical liquid and the diluent.

According to the viscosity adjustment bottle 300 of the embodiment, the porous body 310 includes the plurality of sub-bodies 311 and 312 in which the diameters of the plurality of holes 310p decrease from the upstream side to the downstream side. As a result, mixing of the chemical liquid and the diluent is repeated at a predetermined cycle, and the chemical liquid and the diluent can be mixed more precisely.

According to the viscosity adjustment bottle 300 of the embodiment, the introduction ports 321a and 331a, the discharge port 332a, and the exhaust port 333a are provided on the top surface of the viscosity adjustment bottle 300. As described above, the introduction ports 321a and 331a, the discharge port 332a, and the exhaust port 333a are integrated on one surface of the viscosity adjustment bottle 300, so that the viscosity adjustment bottle 300 can be easily attached to the chemical liquid application apparatus 1. Further, the configuration of the viscosity adjustment bottle attachment unit ATT of the chemical liquid application apparatus 1 can be simplified, and the chemical liquid application apparatus 1 can be miniaturized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A chemical liquid application apparatus comprising:
a processing unit which applies a chemical liquid to a substrate;
a chemical liquid supply unit that is capable of connecting a supply source of the chemical liquid;
a diluent supply unit that is capable of connecting a supply source of a diluent diluting the chemical liquid;
a viscosity adjustment unit including a viscosity adjustment bottle to which the chemical liquid is supplied from the chemical liquid supply unit, to which the diluent is supplied from the diluent supply unit, and which mixes the chemical liquid and the diluent; and
a mixture supply unit which supplies a mixture of the chemical liquid and the diluent to the processing unit, wherein
the viscosity adjustment bottle includes
a first introduction port into which the chemical liquid is introduced,
a second introduction port into which the diluent diluting the chemical liquid is introduced,
a porous body which is connected to the first and second introduction ports and includes a plurality of holes through which the chemical liquid introduced from the first introduction port and the diluent introduced from the second introduction port flow, and
a discharge port which is connected to the porous body and from which the mixture of the chemical liquid and the diluent is discharged.

2. The chemical liquid application apparatus according to claim 1, wherein
diameters of the plurality of holes in the porous body are different according to positions from an upstream side to a downstream side.

3. The chemical liquid application apparatus according to claim 1, wherein
the porous body includes a plurality of sub-bodies arranged from an upstream side to a downstream side, and
in each of the plurality of sub-bodies, diameters of the plurality of holes in the porous body are different according to positions from the upstream side to the downstream side.

4. The chemical liquid application apparatus according to claim 3, wherein
in each of the plurality of sub-bodies, the diameters of the plurality of holes in the porous body decrease from the upstream side to the downstream side.

5. The chemical liquid application apparatus according to claim 1; wherein
an upstream side of the porous body is disposed above a downstream side of the porous body in a direction of gravity.

6. The chemical liquid application apparatus according to claim 1, wherein
the plurality of holes in the porous body is disposed in a grid shape on a cross-section of the porous body orthogonal to a flow direction of the chemical liquid and the diluent, and
the chemical liquid and the diluent are introduced at random positions with respect to the plurality of holes disposed in the grid shape.

7. The chemical liquid application apparatus according to claim 1, wherein
the plurality of holes in the porous body includes
one or more holes which are disposed in a region including a center position of a cross-section of the porous body orthogonal to a flow direction of the chemical liquid and the diluent and into which the chemical liquid is introduced, and
a plurality of holes which is disposed apart from each other in a region surrounding the center position of the cross-section and into which the diluent is introduced.

8. The chemical liquid application apparatus according to claim 1, wherein
the plurality of holes in the porous body includes
one or more holes which are disposed in a region including a center position of a cross-section of the porous body orthogonal to a flow direction of the chemical liquid and the diluent and into which the chemical liquid is introduced, and
one or more holes which are disposed in an annular shape in a region surrounding the center position of the cross-section and into which the diluent is introduced.

9. The chemical liquid application apparatus according to claim 1, wherein
the viscosity adjustment bottle further includes an exhaust port which is connected to the porous body and from which gas in the porous body is exhausted.

10. A chemical liquid application apparatus comprising:
a processing unit which applies a chemical liquid to a substrate;
a chemical liquid supply unit that is capable of connecting a supply source of the chemical liquid;
a diluent supply unit that is capable of connecting a supply source of a diluent diluting the chemical liquid;
a viscosity adjustment unit including a viscosity adjustment bottle attachment unit to which a viscosity adjustment bottle is attachable, the chemical liquid being supplied from the chemical liquid supply unit to the viscosity adjustment bottle, the diluent being supplied from the diluent supply unit to the viscosity adjustment bottle, the viscosity adjustment bottle mixing the chemical liquid and the diluent; and
a mixture supply unit which supplies a mixture of the chemical liquid and the diluent to the processing unit, wherein
the viscosity adjustment bottle attachment unit includes
a first outflow port which outflows the chemical liquid to the viscosity adjustment bottle,
a second outflow port which outflows the diluent diluting the chemical liquid to the viscosity adjustment bottle, and
an inflow port into which the mixture of the chemical liquid and the diluent flows from the viscosity adjustment bottle.

11. The chemical liquid application apparatus according to claim 10, wherein
the viscosity adjustment bottle includes a porous body including a plurality of holes through which the chemical liquid and the diluent supplied to the viscosity adjustment bottle flow, and
the viscosity adjustment bottle is attachable to the viscosity adjustment bottle attachment unit so that an upstream side of the porous body is disposed above a downstream side of the porous body in a direction of gravity.

12. The chemical liquid application apparatus according to claim 10, wherein
the viscosity adjustment bottle attachment unit further includes an exhaust port from which gas in the porous body is exhausted.

13. A viscosity adjustment bottle that is attachable to a chemical liquid application apparatus applying a chemical liquid to a substrate, the viscosity adjustment bottle comprising:
a first introduction port into which the chemical liquid is introduced;
a second introduction port into which a diluent diluting the chemical liquid is introduced;
a porous body which is connected to the first and second introduction ports and includes a plurality of holes through which the chemical liquid introduced from the first introduction port and the diluent introduced from the second introduction port flow, and
a discharge port which is connected to the porous body and from which a mixture of the chemical liquid and the diluent is discharged.

14. The viscosity adjustment bottle according to claim 13, wherein
diameters of the plurality of holes in the porous body are different according to positions from an upstream side to a downstream side.

15. The viscosity adjustment bottle according to claim 13, wherein
the porous body includes a plurality of sub-bodies arranged from an upstream side to a downstream side, and
in each of the plurality of sub-bodies, diameters of the plurality of holes in the porous body are different according to positions from the upstream side to the downstream side.

16. The viscosity adjustment bottle according to claim 15, wherein
in each of the plurality of sub-bodies, the diameters of the plurality of holes in the porous body decrease from the upstream side to the downstream side.

17. The viscosity adjustment bottle according to claim 13, wherein
the plurality of holes in the porous body is disposed in a grid shape on a cross-section of the porous body orthogonal to a flow direction of the chemical liquid and the diluent, and
the chemical liquid and the diluent are introduced at random positions with respect to the plurality of holes disposed in the grid shape.

18. The viscosity adjustment bottle according to claim 13, wherein
the plurality of holes in the porous body includes
one or more holes which are disposed in a region including a center position of a cross-section of the porous body orthogonal to a flow direction of the chemical liquid and the diluent and into which the chemical liquid is introduced, and
a plurality of holes which is disposed apart from each other in a region surrounding the center position of the cross-section and into which the diluent is introduced.

19. The viscosity adjustment bottle according to claim 13, wherein
the plurality of holes in the porous body includes
one or more holes which are disposed in a region including a center position of a cross-section of the porous body orthogonal to a flow direction of the chemical liquid and the diluent and into which the chemical liquid is introduced, and
one or more holes which are disposed in an annular shape in a region surrounding the center position of the cross-section and into which the diluent is introduced.

20. The viscosity adjustment bottle according to claim 13, wherein
the viscosity adjustment bottle further includes an exhaust port which is connected to the porous body and from which gas in the porous body is exhausted.
